(19) United States
(12) Patent Application Publication
(10) Pub. No.: US 2024/0353756 A1
(43) Pub. Date: Oct. 24, 2024

(54) LITHOGRAPHIC METHOD TO ENHANCE ILLUMINATOR TRANSMISSION

(71) Applicant: ASML Netherlands B.V., Veldhoven (NL)

(72) Inventors: Todd R. DOWNEY, Monroe, CT (US); Marianna MANCA, Eindhoven (NL); Widianta GOMULYA, Eindhoven (NL); Kalyan Kumar MANKALA, Bethel, CT (US); Janardan NATH, Norwalk, CT (US)

(73) Assignee: ASML Netherlands B.V., Veldhoven (NL)

(21) Appl. No.: 18/682,789

(22) PCT Filed: Jul. 27, 2022
(86) PCT No.: PCT/EP2022/071140

§ 371 Date: Feb. 9, 2024

Related U.S. Application Data
(60) Provisional application No. 63/232,783, filed on Aug. 13, 2021.

(51) Int. Cl. G03F 7/20

(52) U.S. Cl. CPC G03F 7/2004

(57) ABSTRACT

Systems, apparatuses, and methods are provided for adjusting illumination slit uniformity in a lithographic apparatus. An example method can include determining whether an exposure field for a wafer exposure operation is less than a maximum exposure field of a uniformity correction system. In response to determining that the exposure field is less than the maximum exposure field, the example method can include modifying illumination slit uniformity calibration data associated with the maximum exposure field to generate modified illumination slit uniformity calibration data associated with the exposure field. Subsequently, the example method can include determining an optimal position of a finger assembly of the uniformity correction system based on the modified illumination slit uniformity calibration data.

### CROSS-REFERENCE TO RELATED APPLICATIONS

This application claims priority of U.S. Provisional Patent Application No. 63/232,783, which was filed on Aug. 13, 2021, and which is incorporated herein in its entirety by reference.

### TECHNICAL FIELD

The present disclosure relates to systems and methods for correcting illumination non-uniformities in lithographic apparatuses and systems.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is interchangeably referred to as a mask or a reticle, can be used to generate a circuit pattern to be formed on an individual layer of the IC being formed. This pattern can be transferred onto a target portion (e.g., including part of, one, or several dies) on a substrate (e.g., a silicon wafer). Transfer of the pattern is typically via imaging onto a layer of radiation-sensitive material (e.g., resist) provided on the substrate. In general, a single substrate will contain a network of adjacent target portions that are successively patterned. Traditional lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel (e.g., opposite) to this scanning direction. It is also possible to transfer the pattern from the patterning device to the substrate by imprinting the pattern onto the substrate.

As semiconductor manufacturing processes continue to advance, the dimensions of circuit elements have continually been reduced while the amount of functional elements, such as transistors, per device has been steadily increasing over decades, following a trend commonly referred to as Moore's law. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

Extreme ultraviolet (EUV) radiation, for example, electromagnetic radiation having wavelengths of around 50 nanometers (nm) or less (also sometimes referred to as soft x-rays), and including light at a wavelength of about 13.5 nm, can be used in or with a lithographic apparatus to produce extremely small features in or on substrates, for example, silicon wafers. A lithographic apparatus which uses EUV radiation having a wavelength within a range of 4 nm to 20 nm, for example 6.7 nm or 13.5 nm, can be used to form smaller features on a substrate than a lithographic apparatus which uses, for example, radiation with a wavelength of 193 nm.

Methods to produce EUV light include, but are not necessarily limited to, converting a material that has an element, for example, xenon (Xe), lithium (Li), or tin (Sn), with an emission line in the EUV range to a plasma state. For example, in one such method called laser produced plasma (LPP), the plasma can be produced by irradiating a target material, which is interchangeably referred to as fuel in the context of LPP sources, for example, in the form of a droplet, plate, tape, stream, or cluster of material, with an amplified light beam that can be referred to as a drive laser. For this process, the plasma is typically produced in a sealed vessel, for example, a vacuum chamber, and monitored using various types of metrology equipment.

A lithographic apparatus typically includes an illumination system that conditions radiation generated by a radiation source before the radiation is incident upon a patterning device. The illumination system may, for example, modify one or more properties of the radiation, such as polarization and/or illumination mode. The illumination system may include a uniformity correction system that corrects or reduces non-uniformities (e.g., intensity non-uniformities) present in the radiation. Uniformity correction devices may employ actuated finger assemblies that are inserted into an edge of a radiation beam to correct intensity variations. A spatial breadth of illumination that can be adjusted by a uniformity correction system is dependent on, inter alia, sizes of the finger assemblies and of the actuating devices used to move finger assemblies in the uniformity correction system. Modifying finger parameters from a known working design is not trivial as such modifications can lead to undesirable alterations of one or more properties of a radiation beam.

In order to achieve tolerances of image quality on a patterning device and substrate, an illumination beam having a controlled uniformity is desirable. It is common for an illumination beam to have a non-uniform intensity profile before reflecting off of or transmitting through a patterning device. It is desirable at various stages in a lithographic process that the illumination beam be controlled to achieve improved uniformity. Uniformity can refer to a constant intensity across a pertinent cross section of the illumination beam, but can also refer to the ability to control the illumination to achieve selected uniformity parameters. A patterning device imparts a pattern onto a beam of radiation that is then projected onto a substrate. Image quality of this projected beam is affected by the uniformity of the beam.

### SUMMARY

Accordingly, it is desirable to control illumination uniformity so that lithographic tools perform lithography processes as efficiently as possible for maximizing manufacturing capacity and yield rates, minimizing manufacturing defects, and reducing cost per device.

The present disclosure describes various aspects of systems, apparatuses, and methods for adjusting illumination slit uniformity in a lithographic apparatus.

In some aspects, the present disclosure describes a system. The system can include a uniformity correction system that includes a plurality of finger assemblies and a controller. The plurality of finger assemblies can define a maximum exposure field of the uniformity correction system, and a subset of the plurality of finger assemblies can define an exposure field for a wafer exposure operation. The controller can be configured to determine whether the exposure field is less than the maximum exposure field. In response to a determination that the exposure field is less than the maximum exposure field, the controller can be further configured to modify illumination slit uniformity calibration data associated with the maximum exposure field to generate modified illumination slit uniformity calibration data associated with the exposure field. Subsequently, the controller can be configured to determine an optimal position of a finger assembly in the subset of the plurality of finger assemblies based on the modified illumination slit uniformity calibration data.

In some aspects, the maximum exposure field can correspond to a maximum illumination slit width of the uniformity correction system, and the exposure field can correspond to an illumination slit width that is less than the maximum illumination slit width. In some aspects, the maximum exposure field can correspond to a full field of the uniformity correction system, and the exposure field can correspond to a partial field (e.g., a shifted or potentially shifted half field) of the uniformity correction system.

In some aspects, the uniformity correction system can further include a motion control system coupled to the finger assembly and configured to adjust the optimal position of the finger assembly. In some aspects, the controller can be further configured to determine a change in a shape of the finger assembly.

In one example, the controller can be further configured to determine a change in a position of an optical edge of a fingertip of the finger assembly based on a growth of the fingertip in response to an exposure of the fingertip to deep ultraviolet (DUV) radiation or extreme ultraviolet (EUV) radiation and determine the change in the shape of the finger assembly based on the determined change in the position of the optical edge of the fingertip of the finger assembly.

In another example, the controller can be further configured to measure a change in a position of a reference mark disposed on the finger assembly and determine the change in the shape of the finger assembly based on the measured change in the position of the reference mark.

In some aspects, the controller can be further configured to generate a control signal configured instruct the motion control system to adjust the optimal position of the finger assembly based on the modified illumination slit uniformity calibration data and the determined change in the shape of the finger assembly; and transmit the control signal to the motion control system.

In some aspects, the present disclosure describes an apparatus. The apparatus can include a controller configured to determine whether an exposure field for a wafer exposure operation is less than a maximum exposure field of a uniformity correction system. In response to a determination that the exposure field is less than the maximum exposure field, the controller can be further configured to modify illumination slit uniformity calibration data associated with the maximum exposure field to generate modified illumination slit uniformity calibration data associated with the exposure field. Subsequently, the controller can be configured to determine an optimal position of a finger assembly of the uniformity correction system based on the modified illumination slit uniformity calibration data.

In some aspects, the uniformity correction system can include a plurality of finger assemblies. In some aspects, the maximum exposure field can be defined by the plurality of finger assemblies, and the exposure field can be defined by a subset of the plurality of finger assemblies. In some aspects, the subset of the plurality of finger assemblies comprises the finger assembly.

In some aspects, the maximum exposure field can correspond to a maximum illumination slit width of the uniformity correction system, and the exposure field can correspond to an illumination slit width that is less than the maximum illumination slit width. In some aspects, the maximum exposure field can correspond to a full field of the uniformity correction system, and the exposure field can correspond to a partial field of the uniformity correction system.

In some aspects, the controller can be further configured to determine a change in a shape of the finger assembly.

In one example, the controller can be configured to determine a change in a position of an optical edge of a fingertip of the finger assembly based on a growth of the fingertip in response to an exposure of the fingertip to DUV radiation or EUV radiation and determine the change in the shape of the finger assembly based on the determined change in the position of the optical edge of the fingertip of the finger assembly.

In another example, the controller can be configured to measure a change in a position of a reference mark disposed on the finger assembly and determine the change in the shape of the finger assembly based on the measured change in the position of the reference mark.

In some aspects, the controller can be further configured to generate a control signal configured instruct a motion control system coupled to the finger assembly to adjust the optimal position of the finger assembly based on the modified illumination slit uniformity calibration data and the determined change in the shape of the finger assembly; and transmit the control signal to the motion control system.

In some aspects, the present disclosure describes a method for adjusting illumination slit uniformity in a lithographic apparatus. The method can include determining, by a controller, whether an exposure field for a wafer exposure operation is less than a maximum exposure field of a uniformity correction system. In response to determining that the exposure field is less than the maximum exposure field, the method can further include modifying, by the controller, illumination slit uniformity calibration data associated with the maximum exposure field to generate modified illumination slit uniformity calibration data associated with the exposure field. Subsequently, the method can include determining, by the controller, an optimal position of a finger assembly of the uniformity correction system based on the modified illumination slit uniformity calibration data.

In some aspects, the uniformity correction system can include a plurality of finger assemblies. In some aspects, the maximum exposure field can be defined by the plurality of finger assemblies, and the exposure field can be defined by a subset of the plurality of finger assemblies. In some aspects, the subset of the plurality of finger assemblies comprises the finger assembly.

In some aspects, the maximum exposure field can correspond to a maximum illumination slit width of the uniformity correction system, and the exposure field can correspond to an illumination slit width that is less than the maximum illumination slit width. In some aspects, the maximum exposure field can correspond to a full field of the uniformity correction system, and the exposure field can correspond to a partial field of the uniformity correction system.

In some aspects, the method can further include determining, by the controller, a change in a shape of the finger assembly. In one example, the determining the change in the shape of the finger assembly can include: determining, by the controller, a change in a position of an optical edge of a fingertip of the finger assembly based on a growth of the fingertip in response to an exposure of the fingertip to DUV radiation or EUV radiation; and determining, by the controller, the change in the shape of the finger assembly based on the determined change in the position of the optical edge of the fingertip of the finger assembly.

In another example, the determining the change in the shape of the finger assembly can include measuring, by the controller, a change in a position of a reference mark disposed on the finger assembly and determining, by the controller, the change in the shape of the finger assembly based on the measured change in the position of the reference mark.

In some aspects, the method can further include generating, by the controller, a control signal configured to instruct a motion control system coupled to the finger assembly to adjust the optimal position of the finger assembly based on the modified illumination slit uniformity calibration data and the determined change in the shape of the finger assembly and transmitting, by the controller, the control signal to the motion control system.

Further features, as well as the structure and operation of various aspects, are described in detail below with reference to the accompanying drawings. It is noted that the disclosure is not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS

The accompanying drawings, which are incorporated herein and form part of the specification, illustrate the present disclosure and, together with the description, further serve to explain the principles of the aspects of this disclosure and to enable a person skilled in the relevant art(s) to make and use the aspects of this disclosure.

FIG. 1A is a schematic illustration of an example reflective lithographic apparatus according to some aspects of the present disclosure or portion(s) thereof.

FIG. 1B is a schematic illustration of an example transmissive lithographic apparatus according to some aspects of the present disclosure or portion(s) thereof.

FIG. 2 is a more detailed schematic illustration of the reflective lithographic apparatus shown in FIG. 1A according to some aspects of the present disclosure or portion(s) thereof.

FIG. 3 is a schematic illustration of an example lithographic cell according to some aspects of the present disclosure or portion(s) thereof.

FIG. 4 is a schematic illustration of an example radiation source for an example reflective lithographic apparatus according to some aspects of the present disclosure or portion(s) thereof.

FIGS. 5A and 5B are schematic illustrations of an example illumination uniformity correction system according to some aspects of the present disclosure or portion(s) thereof.

FIG. 6 is an example graph showing example illumination slit uniformity calibration data for a maximum exposure field according to some aspects of the present disclosure or portion(s) thereof.

FIG. 7 is an example graph showing example modified illumination slit uniformity calibration data for a partial exposure field according to some aspects of the present disclosure or portion(s) thereof.

FIG. 8 is an example method for adjusting illumination slit uniformity in a lithographic apparatus according to some aspects of the present disclosure or portion(s) thereof.

FIG. 9 is an example computer system for implementing some aspects of the present disclosure or portion(s) thereof.

The features and advantages of the present disclosure will become more apparent from the detailed description set forth below when taken in conjunction with the drawings, in which like reference characters identify corresponding elements throughout. In the drawings, unless otherwise indicated, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) merely describe the present disclosure. The scope of the disclosure is not limited to the disclosed embodiment(s). The breadth and scope of the disclosure are defined by the claims appended hereto and their equivalents.

The embodiment(s) described, and references in the specification to “one embodiment,” “an embodiment,” “an example embodiment,” etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

### Overview

An example illumination uniformity correction system referred to as a “Unicom” can adjust slit uniformity in the cross-scan direction, attenuating illumination “hot spots” by introducing a set of finger assemblies or “fingers” into the illumination slit. The Unicom can be configured to operate in one of two “modes”: (1) a first mode that concerns uniformity correction per wafer to correct for illumination effects; and (2) a second mode in which slit uniformity is modified per die to correct for wafer and process effects and in which uniformity correction changes in parallel to stepping dies.

As incoming light (e.g., DUV or EUV radiation) heats the Unicom finger tips, the unmeasured distance from the Unicom position measurement and the fingertip can change, causing a drift in the slit uniformity. For instance, as power increases in a lithographic apparatus, the expected critical dimension (CD) impact of uniformity drift can increase from about 0.06 nm (<600 W source power) to greater than or equal to about 0.1 nm (≥600 W source power). CD impact can be equal to about 0.3 times the percentage of uniformity. CD uniformity (CDU) requirements can be between about 0.7 nm and about 1.2 nm. In some examples, slit uniformity drift may not be compensated.

In one example, illumination slit uniformity correction can be performed by the Unicom module described in U.S. Pat. No. 8,629,973, issued Jan. 14, 2014, and titled “LITHOGRAPHIC APPARATUS AND METHOD FOR ILLUMINATION UNIFORMITY CORRECTION AND UNIFORMITY DRIFT COMPENSATION,” which is incorporated by reference herein in its entirety. During calibration, the position of each light-blocking “finger” is determined based on the entire illumination slit-width (e.g., 26 mm at wafer-scale). Uniformity Refresh (UR) functionality provides post-calibration drift protection for each lot and, optionally, each wafer. However, in the case of small-fields (e.g., exposure field-width less than 26 mm), UR may not provide optimal compensation that minimizes the Unicom transmission loss in all cases.

In contrast, some aspects of the present disclosure can provide for an updated small-field UR functionality that provides slit uniformity correction in the presence of drift in addition to minimizing the transmission loss. By determining an optimization target based on only the data within the field-width, the optimization result can contain the transmission benefit. Additionally, depending on the shape of the to-be corrected slit, and the location of the small-field image within the slit, more or less benefit can be achieved.

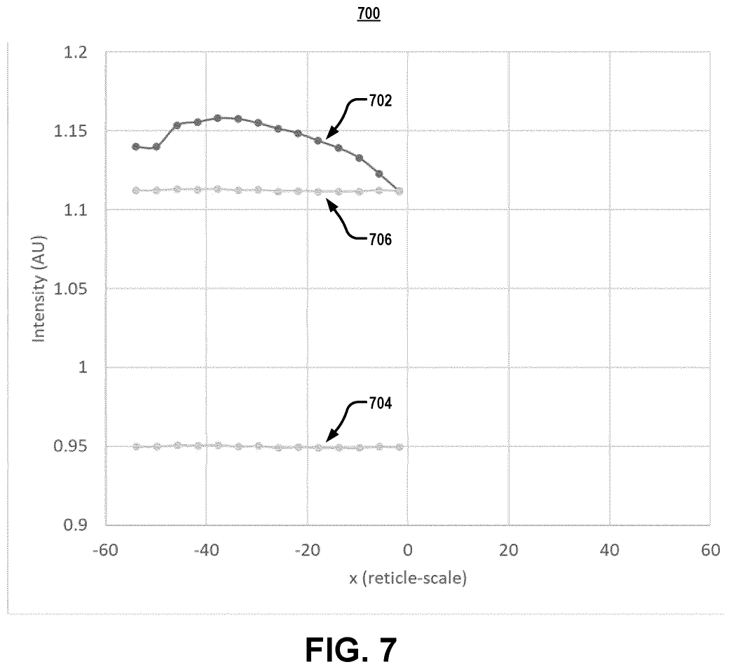

There are many exemplary aspects to the systems, apparatuses, methods, and computer program products disclosed herein. For example, aspects of the present disclosure provide for decreasing the CD drift and CDU impact from the Unicom. In another example, aspects of the present disclosure provide for increasing illuminator transmission and throughput. As a result, illuminator transmission can be optimized for substantially all cases (e.g., greater than 15% benefit for the example embodiment described with reference to FIG. 7).

Before describing such aspects in more detail, however, it is instructive to present an example environment in which aspects of the present disclosure can be implemented.

### Example Lithographic Systems

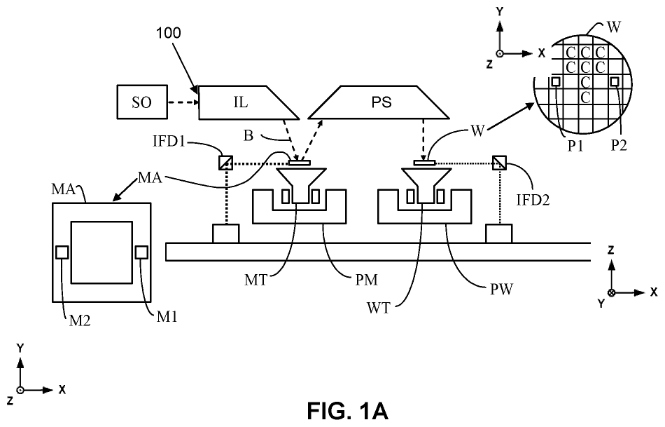

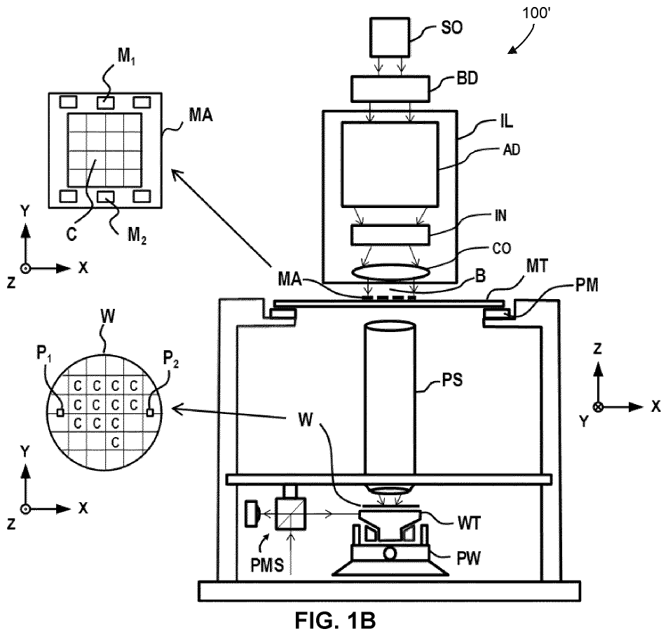

FIGS. 1A and 1B are schematic illustrations of a lithographic apparatus 100 and a lithographic apparatus 100′, respectively, in which aspects of the present disclosure can be implemented. As shown in FIGS. 1A and 1B, the lithographic apparatuses 100 and 100′ are illustrated from a point of view (e.g., a side view) that is normal to the XZ plane (e.g., the X-axis points to the right, the Z-axis points upward, and the Y-axis points into the page away from the viewer), while the patterning device MA and the substrate W are presented from additional points of view (e.g., a top view) that are normal to the XY plane (e.g., the X-axis points to the right, the Y-axis points upward, and the Z-axis points out of the page toward the viewer).

In some aspects, the lithographic apparatus 100 and/or the lithographic apparatus 100′ can include one or more of the following structures: an illumination system IL (e.g., an illuminator) configured to condition a radiation beam B (e.g., a DUV radiation beam or an EUV radiation beam); a support structure MT (e.g., a mask table) configured to support a patterning device MA (e.g., a mask, a reticle, or a dynamic patterning device) and connected to a first positioner PM configured to accurately position the patterning device MA; and, a substrate holder such as a substrate table WT (e.g., a wafer table) configured to hold a substrate W (e.g., a resist-coated wafer) and connected to a second positioner PW configured to accurately position the substrate W. Lithographic apparatuses 100 and 100′ also have a projection system PS (e.g., a refractive projection lens system) configured to project a pattern imparted to the radiation beam B by patterning device MA onto a target portion C (e.g., a portion including one or more dies) of the substrate W. In lithographic apparatus 100, the patterning device MA and the projection system PS are reflective. In lithographic apparatus 100′, the patterning device MA and the projection system PS are transmissive.

In some aspects, in operation, the illumination system IL can receive a radiation beam from a radiation source SO (e.g., via a beam delivery system BD shown in FIG. 1B). The illumination system IL can include various types of optical structures, such as refractive, reflective, catadioptric, magnetic, electromagnetic, electrostatic, and other types of optical components, or any combination thereof, for directing, shaping, or controlling radiation. In some aspects, the illumination system IL can be configured to condition the radiation beam B to have a desired spatial and angular intensity distribution in its cross-section at a plane of the patterning device MA.

In some aspects, the support structure MT can hold the patterning device MA in a manner that depends on the orientation of the patterning device MA with respect to a reference frame, the design of at least one of the lithographic apparatuses 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

In some aspects, the patterning device MA can be transmissive (as in lithographic apparatus 100′ of FIG. 1B) or reflective (as in lithographic apparatus 100 of FIG. 1A). The patterning device MA can include various structures such as reticles, masks, programmable mirror arrays, programmable LCD panels, other suitable structures, or combinations thereof. Masks can include mask types such as binary, alternating phase shift, or attenuated phase shift, as well as various hybrid mask types. In one example, a programmable mirror array can include a matrix arrangement of small mirrors, each of which can be individually tilted so as to reflect an incoming radiation beam in different directions. The tilted mirrors can impart a pattern in the radiation beam B, which is reflected by a matrix of small mirrors.

The term “projection system” PS should be interpreted broadly and can encompass any type of projection system, including refractive, reflective, catadioptric, magnetic, anamorphic, electromagnetic, and electrostatic optical systems, or any combination thereof, as appropriate for the exposure radiation being used, and/or for other factors such as the use of an immersion liquid (e.g., on the substrate W) or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps. In addition, any use herein of the term “projection lens” can be interpreted, in some aspects, as synonymous with the more general term “projection system” PS.

In some aspects, the lithographic apparatus 100 and/or the lithographic apparatus 100′ can be of a type having two (e.g., “dual stage”) or more substrate tables WT and/or two or more mask tables). In such “multiple stage” machines, the additional substrate tables WT can be used in parallel, or preparatory steps can be carried out on one or more tables while one or more other substrate tables WT are being used for exposure. In one example, steps in preparation of a subsequent exposure of the substrate W can be carried out on the substrate W located on one of the substrate tables WT while another substrate W located on another of the substrate tables WT is being used for exposing a pattern on another substrate W. In some aspects, the additional table may not be a substrate table WT.

In some aspects, in addition to the substrate table WT, the lithographic apparatus 100 and/or the lithographic apparatus 100′ can include a measurement stage. The measurement stage can be arranged to hold a sensor. The sensor can be arranged to measure a property of the projection system PS, a property of the radiation beam B, or both. In some aspects, the measurement stage can hold multiple sensors. In some aspects, the measurement stage can move beneath the projection system PS when the substrate table WT is away from the projection system PS.

In some aspects, the lithographic apparatus 100 and/or the lithographic apparatus 100′ can also be of a type wherein at least a portion of the substrate can be covered by a liquid having a relatively high refractive index, e.g., water, so as to fill a space between the projection system PS and the substrate W. An immersion liquid can also be applied to other spaces in the lithographic apparatus, for example, between the patterning device MA and the projection system PS. Immersion techniques provide for increasing the numerical aperture of projection systems. The term “immersion” as used herein does not mean that a structure, such as a substrate, must be submerged in liquid, but rather only means that liquid is located between the projection system and the substrate during exposure. Various immersion techniques are described in U.S. Pat. No. 6,952,253, issued Oct. 4, 2005, and titled “LITHOGRAPHIC APPARATUS AND DEVICE MANUFACTURING METHOD,” which is incorporated by reference herein in its entirety.

Referring to FIGS. 1A and 1B, the illumination system IL receives a radiation beam B from a radiation source SO. The radiation source SO and the lithographic apparatus 100 or 100′ can be separate physical entities, for example, when the radiation source SO is an excimer laser. In such cases, the radiation source SO is not considered to form part of the lithographic apparatus 100 or 100′, and the radiation beam B passes from the radiation source SO to the illumination system IL with the aid of a beam delivery system BD (e.g., shown in FIG. 1B) including, for example, suitable directing mirrors and/or a beam expander. In other cases, the radiation source SO can be an integral part of the lithographic apparatus 100 or 100′, for example, when the radiation source SO is a mercury lamp. The radiation source SO and the illuminator IL, together with the beam delivery system BD, if required, can be referred to as a radiation system.

In some aspects, the illumination system IL can include an adjuster AD for adjusting the angular intensity distribution of the radiation beam. Generally, at least the outer and/or inner radial extent (commonly referred to as “o-outer” and “o-inner,” respectively) of the intensity distribution in a pupil plane of the illuminator can be adjusted. In addition, the illumination system IL can include various other components, such as an integrator IN and a radiation collector CO (e.g., a condenser or collector optic). In some aspects, the illumination system IL can be used to condition the radiation beam B to have a desired uniformity and intensity distribution in its cross section.

Referring to FIG. 1A, in operation, the radiation beam B can be incident on the patterning device MA (e.g., a mask, reticle, programmable mirror array, programmable LCD panel, any other suitable structure or combination thereof), which can be held on the support structure MT (e.g., a mask table), and can be patterned by the pattern (e.g., design layout) present on the patterning device MA. In lithographic apparatus 100, the radiation beam B can be reflected from the patterning device MA. Having traversed (e.g., after being reflected from) the patterning device MA, the radiation beam B can pass through the projection system PS, which can focus the radiation beam B onto a target portion C of the substrate W or onto a sensor arranged at a stage.

In some aspects, with the aid of the second positioner PW and position sensor IFD2 (e.g., an interferometric device, linear encoder, or capacitive sensor), the substrate table WT can be moved accurately, e.g., so as to position different target portions C in the path of the radiation beam B. Similarly, the first positioner PM and another position sensor IFD1 (e.g., an interferometric device, linear encoder, or capacitive sensor) can be used to accurately position the patterning device MA with respect to the path of the radiation beam B.

In some aspects, patterning device MA and substrate W can be aligned using mask alignment marks M1 and M2 and substrate alignment marks P1 and P2. Although FIGS. 1A and 1B illustrate the substrate alignment marks P1 and P2 as occupying dedicated target portions, the substrate alignment marks P1 and P2 may be located in spaces between target portions. Substrate alignment marks P1 and P2 are known as scribe-lane alignment marks when they are located between the target portions C. Substrate alignment marks P1 and P2 can also be arranged in the target portion C area as in-die marks. These in-die marks can also be used as metrology marks, for example, for overlay measurements.

In some aspects, for purposes of illustration and not limitation, one or more of the figures herein can utilize a Cartesian coordinate system. The Cartesian coordinate system includes three axes: an X-axis; a Y-axis; and a Z-axis. Each of the three axes is orthogonal to the other two axes (e.g., the X-axis is orthogonal to the Y-axis and the Z-axis, the Y-axis is orthogonal to the X-axis and the Z-axis, the Z-axis is orthogonal to the X-axis and the Y-axis). A rotation around the X-axis is referred to as an Rx-rotation. A rotation around the Y-axis is referred to as an Ry-rotation. A rotation around about the Z-axis is referred to as an Rz-rotation. In some aspects, the X-axis and the Y-axis define a horizontal plane, whereas the Z-axis is in a vertical direction. In some aspects, the orientation of the Cartesian coordinate system may be different, for example, such that the Z-axis has a component along the horizontal plane. In some aspects, another coordinate system, such as a cylindrical coordinate system, can be used.

Referring to FIG. 1B, the radiation beam B is incident on the patterning device MA, which is held on the support structure MT, and is patterned by the patterning device MA. Having traversed the patterning device MA, the radiation beam B passes through the projection system PS, which focuses the beam onto a target portion C of the substrate W. In some aspects, the projection system PS can have a pupil conjugate to an illumination system pupil. In some aspects, portions of radiation can emanate from the intensity distribution at the illumination system pupil and traverse a mask pattern without being affected by diffraction at the mask pattern MP and create an image of the intensity distribution at the illumination system pupil.

The projection system PS projects an image MP′ of the mask pattern MP, where image MP′ is formed by diffracted beams produced from the mask pattern MP by radiation from the intensity distribution, onto a resist layer coated on the substrate W. For example, the mask pattern MP can include an array of lines and spaces. A diffraction of radiation at the array and different from zeroth-order diffraction generates diverted diffracted beams with a change of direction in a direction perpendicular to the lines. Reflected light (e.g., zeroth-order diffracted beams) traverses the pattern without any change in propagation direction. The zeroth-order diffracted beams traverse an upper lens or upper lens group of the projection system PS, upstream of the pupil conjugate of the projection system PS, to reach the pupil conjugate. The portion of the intensity distribution in the plane of the pupil conjugate and associated with the zeroth-order diffracted beams is an image of the intensity distribution in the illumination system pupil of the illumination system IL. In some aspects, an aperture device can be disposed at, or substantially at, a plane that includes the pupil conjugate of the projection system PS.

The projection system PS is arranged to capture, by means of a lens or lens group, not only the zeroth-order diffracted beams, but also first-order or first- and higher-order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the substrate W to create an image of the mask pattern MP at highest possible resolution and process window (e.g., usable depth of focus in combination with tolerable exposure dose deviations). In some aspects, astigmatism aberration can be reduced by providing radiation poles (not shown) in opposite quadrants of an illumination system pupil. Further, in some aspects, astigmatism aberration can be reduced by blocking the zeroth-order beams in the pupil conjugate of the projection system PS associated with radiation poles in opposite quadrants. This is described in more detail in U.S. Pat. No. 7,511,799, issued Mar. 31, 2009, and titled “LITHOGRAPHIC PROJECTION APPARATUS AND A DEVICE MANUFACTURING METHOD,” which is incorporated by reference herein in its entirety.

In some aspects, with the aid of the second positioner PW and a position measurement system PMS (e.g., including a position sensor such as an interferometric device, linear encoder, or capacitive sensor), the substrate table WT can be moved accurately, e.g., so as to position different target portions C in the path of the radiation beam B at a focused and aligned position. Similarly, the first positioner PM and another position sensor (e.g., an interferometric device, linear encoder, or capacitive sensor) (not shown in FIG. 1B) can be used to accurately position the patterning device MA with respect to the path of the radiation beam B (e.g., after mechanical retrieval from a mask library or during a scan). Patterning device MA and substrate W can be aligned using mask alignment marks M1 and M2 and substrate alignment marks P1 and P2.

In general, movement of the support structure MT can be realized with the aid of a long-stroke positioner (coarse positioning) and a short-stroke positioner (fine positioning), which form part of the first positioner PM. Similarly, movement of the substrate table WT can be realized using a long-stroke positioner and a short-stroke positioner, which form part of the second positioner PW. In the case of a stepper (as opposed to a scanner), the support structure MT can be connected to a short-stroke actuator only or can be fixed. Patterning device MA and substrate W can be aligned using mask alignment marks M1 and M2, and substrate alignment marks P1 and P2. Although the substrate alignment marks (as illustrated) occupy dedicated target portions, they can be located in spaces between target portions (e.g., scribe-lane alignment marks). Similarly, in situations in which more than one die is provided on the patterning device MA, the mask alignment marks M1 and M2 can be located between the dies.

Support structure MT and patterning device MA can be in a vacuum chamber V, where an in-vacuum robot can be used to move patterning devices such as a mask in and out of vacuum chamber. Alternatively, when support structure MT and patterning device MA are outside of the vacuum chamber, an out-of-vacuum robot can be used for various transportation operations, similar to the in-vacuum robot. In some instances, both the in-vacuum and out-of-vacuum robots need to be calibrated for a smooth transfer of any payload (e.g., a mask) to a fixed kinematic mount of a transfer station.

In some aspects, the lithographic apparatuses 100 and 100′ can be used in at least one of the following modes:

1. In step mode, the support structure MT and the substrate table WT are kept essentially stationary, while an entire pattern imparted to the radiation beam B is projected onto a target portion C at one time (e.g., a single static exposure). The substrate table WT is then shifted in the X and/or Y direction so that a different target portion C can be exposed.

2. In scan mode, the support structure MT and the substrate table WT are scanned synchronously while a pattern imparted to the radiation beam B is projected onto a target portion C (e.g., a single dynamic exposure). The velocity and direction of the substrate table WT relative to the support structure MT (e.g., mask table) can be determined by the (de-) magnification and image reversal characteristics of the projection system PS.

3. In another mode, the support structure MT is kept substantially stationary holding a programmable patterning device MA, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device MA, such as a programmable mirror array.

In some aspects, the lithographic apparatuses 100 and 100′ can employ combinations and/or variations of the above-described modes of use or entirely different modes of use.

In some aspects, as shown in FIG. 1A, the lithographic apparatus 100 can include an EUV source configured to generate an EUV radiation beam B for EUV lithography. In general, the EUV source can be configured in a radiation source SO, and a corresponding illumination system IL can be configured to condition the EUV radiation beam B of the EUV source.

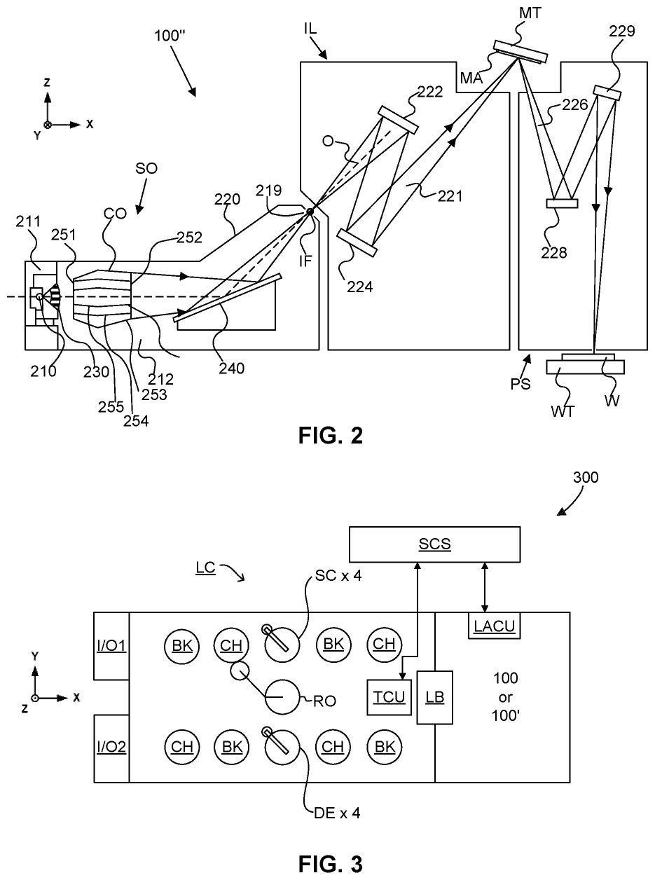

FIG. 2 shows the lithographic apparatus 100 in more detail, including the radiation source SO (e.g., a source collector apparatus), the illumination system IL, and the projection system PS. As shown in FIG. 2, the lithographic apparatus 100 is illustrated from a point of view (e.g., a side view) that is normal to the XZ plane (e.g., the X-axis points to the right and the Z-axis points upward).

The radiation source SO is constructed and arranged such that a vacuum environment can be maintained in an enclosing structure 220. The radiation source SO includes a source chamber 211 and a collector chamber 212 and is configured to produce and transmit EUV radiation. EUV radiation can be produced by a gas or vapor, for example xenon (Xe) gas, lithium (Li) vapor, or tin (Sn) vapor in which an EUV radiation emitting plasma 210 is created to emit radiation in the EUV range of the electromagnetic spectrum. The EUV radiation emitting plasma 210, at least partially ionized, can be created by, for example, an electrical discharge or a laser beam. Partial pressures of, for example, about 10.0 pascals (Pa) of Xe gas, Li vapor, Sn vapor, or any other suitable gas or vapor can be used for efficient generation of the radiation. In some aspects, a plasma of excited tin is provided to produce EUV radiation.

The radiation emitted by the EUV radiation emitting plasma 210 is passed from the source chamber 211 into the collector chamber 212 via an optional gas barrier or contaminant trap 230 (e.g., in some cases also referred to as contaminant barrier or foil trap), which is positioned in or behind an opening in the source chamber 211. The contaminant trap 230 can include a channel structure. Contaminant trap 230 can also include a gas barrier or a combination of a gas barrier and a channel structure. The contaminant trap 230 further indicated herein at least includes a channel structure.

The collector chamber 212 can include a radiation collector CO (e.g., a condenser or collector optic), which can be a so-called grazing incidence collector. Radiation collector CO has an upstream radiation collector side 251 and a downstream radiation collector side 252. Radiation that traverses radiation collector CO can be reflected off a grating spectral filter 240 to be focused in a virtual source point IF. The virtual source point IF is commonly referred to as the intermediate focus, and the source collector apparatus is arranged such that the virtual source point IF is located at or near an opening 219 in the enclosing structure 220. The virtual source point IF is an image of the EUV radiation emitting plasma 210. The grating spectral filter 240 can be used to suppress infrared (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the radiation beam 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination system IL and projection system PS. Optionally, the grating spectral filter 240 can be present depending upon the type of lithographic apparatus. Further, there can be more mirrors present than those shown in the FIG. 2. For example, there can be one to six additional reflective elements present in the projection system PS than shown in FIG. 2.

Radiation collector CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a radiation collector CO of this type is preferably used in combination with a discharge produced plasma (DPP) source.

### Example Lithographic Cell

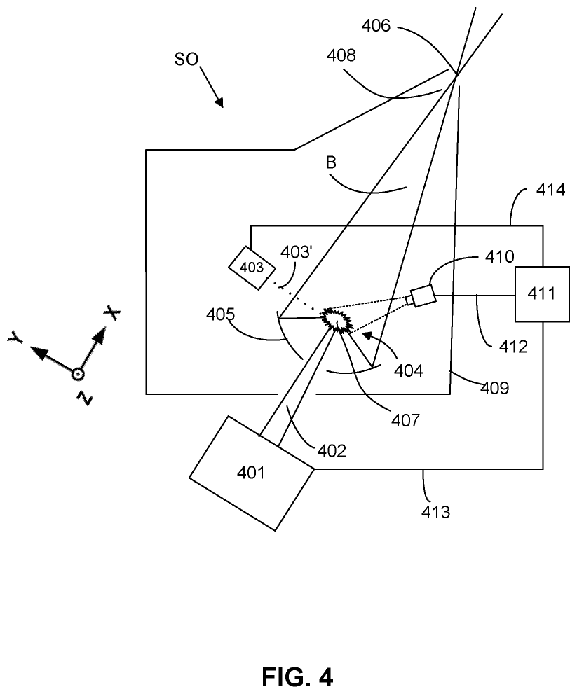

FIG. 3 shows a lithographic cell 300, also sometimes referred to a lithocell or cluster. As shown in FIG. 3, the lithographic cell 300 is illustrated from a point of view (e.g., a top view) that is normal to the XY plane (e.g., the X-axis points to the right and the Y-axis points upward).

Lithographic apparatus 100 or 100′ can form part of lithographic cell 300. Lithographic cell 300 can also include one or more apparatuses to perform pre- and post-exposure processes on a substrate. For example, these apparatuses can include spin coaters SC to deposit resist layers, developers DE to develop exposed resist, chill plates CH, and bake plates BK. A substrate handler RO (e.g., a robot) picks up substrates from input/output ports I/O1 and I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Radiation Source

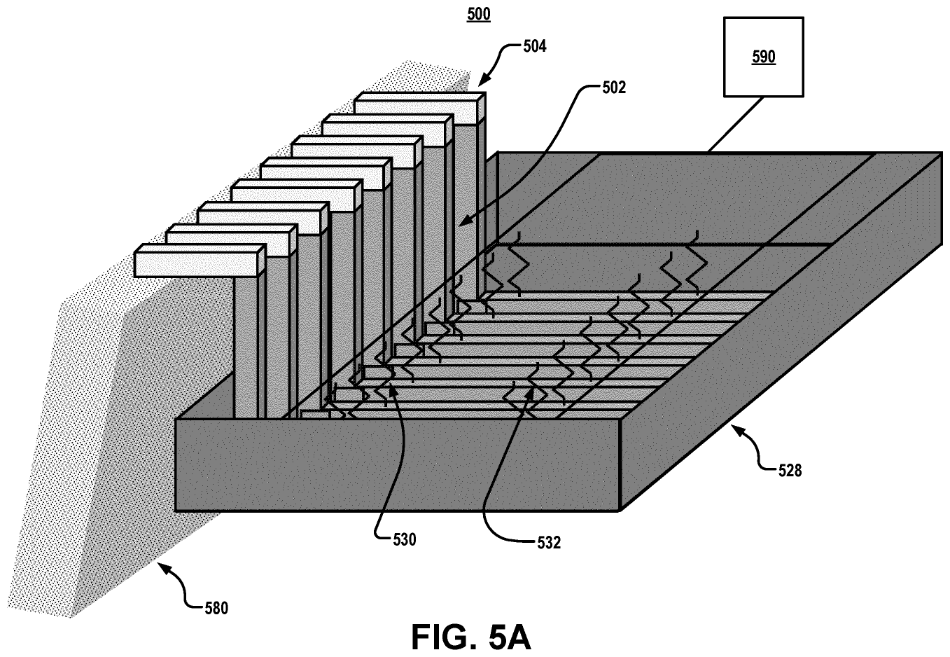

An example of the radiation source SO for an example reflective lithographic apparatus (e.g., lithographic apparatus 100 of FIG. 1A) is shown in FIG. 4. As shown in FIG. 4, the radiation source SO is illustrated from a point of view (e.g., a top view) that is normal to the XY plane as described below.

The radiation source SO shown in FIG. 4 is of a type which can be referred to as a laser produced plasma (LPP) source. A laser system 401, which can for example include a carbon dioxide (CO₂) laser, is arranged to deposit energy via one or more laser beams 402 into fuel targets 403′, such as one or more discrete tin (Sn) droplets, which are provided from a fuel target generator 403 (e.g., example, fuel emitter, droplet generator). According to some aspects, laser system 401 can be, or can operate in the fashion of, a pulsed, continuous wave or quasi-continuous wave laser. The trajectory of fuel targets 403′ (e.g., example, droplets) emitted from the fuel target generator 403 can be parallel to an X-axis. According to some aspects, the one or more laser beams 402 propagate in a direction parallel to a Y-axis, which is perpendicular to the X-axis. A Z-axis is perpendicular to both the X-axis and the Y-axis and extends generally into (or out of) the plane of the page, but in other aspects, other configurations are used. In some embodiments, the one or more laser beams 402 can propagate in a direction other than parallel to the Y-axis (e.g., in a direction other than orthogonal to the X-axis direction of the trajectory of the fuel targets 403′).

In some aspects, the one or more laser beams 402 can include a pre-pulse laser beam and a main pulse laser beam. In such aspects, the laser system 401 can be configured to hit each of the fuel targets 403′ with a pre-pulse laser beam to generate a modified fuel target. The laser system 401 can be further configured to hit each of the modified fuel targets with a main pulse laser beam to generate the plasma 407.

Although tin is referred to in the following description, any suitable target material can be used. The target material can for example be in liquid form, and can for example be a metal or alloy. Fuel target generator 403 can include a nozzle configured to direct tin, e.g., in the form of fuel targets 403′ (e.g., discrete droplets) along a trajectory towards a plasma formation region 404. Throughout the remainder of the description, references to “fuel”, “fuel target” or “fuel droplet” are to be understood as referring to the target material (e.g., droplets) emitted by fuel target generator 403. Fuel target generator 403 can include a fuel emitter. The one or more laser beams 402 are incident upon the target material (e.g., tin) at the plasma formation region 404. The deposition of laser energy into the target material creates a plasma 407 at the plasma formation region 404. Radiation, including EUV radiation, is emitted from the plasma 407 during de-excitation and recombination of ions and electrons of the plasma.

The EUV radiation is collected and focused by a radiation collector 405 (e.g., radiation collector CO). In some aspects, radiation collector 405 can include a near normal-incidence radiation collector (sometimes referred to more generally as a normal-incidence radiation collector). The radiation collector 405 can be a multilayer structure, which is arranged to reflect EUV radiation (e.g., EUV radiation having a desired wavelength such as about 13.5 nm). According to some aspects, radiation collector 405 can have an ellipsoidal configuration, having two focal points. A first focal point can be at the plasma formation region 404, and a second focal point can be at an intermediate focus 406, as discussed herein.

In some aspects, laser system 401 can be located at a relatively long distance from the radiation source SO. Where this is the case, the one or more laser beams 402 can be passed from laser system 401 to the radiation source SO with the aid of a beam delivery system (not shown) including, for example, suitable directing mirrors and/or a beam expander, and/or other optics. Laser system 401 and the radiation source SO can together be considered to be a radiation system.

Radiation that is reflected by radiation collector 405 forms a radiation beam B. The radiation beam B is focused at a point (e.g., the intermediate focus 406) to form an image of plasma formation region 404, which acts as a virtual radiation source for the illumination system IL. The point at which the radiation beam B is focused can be referred to as the intermediate focus (IF) (e.g., intermediate focus 406). The radiation source SO is arranged such that the intermediate focus 406 is located at or near to an opening 408 in an enclosing structure 409 of the radiation source SO.

The radiation beam B passes from the radiation source SO into the illumination system IL, which is configured to condition the radiation beam B. The radiation beam B passes from the illumination system IL and is incident upon the patterning device MA held by the support structure MT. The patterning device MA reflects and patterns the radiation beam B. Following reflection from the patterning device MA the patterned radiation beam B enters the projection system PS. The projection system includes a plurality of mirrors, which are configured to project the radiation beam B onto a substrate W held by the substrate table WT. The projection system PS can apply a reduction factor to the radiation beam, forming an image with features that are smaller than corresponding features on the patterning device MA. For example, a reduction factor of four can be applied. Although the projection system PS is shown as having two mirrors in FIG. 2, the projection system can include any number of mirrors (e.g., six mirrors).

The radiation source SO can also include components which are not illustrated in FIG. 4. For example, a spectral filter can be provided in the radiation source SO. The spectral filter can be substantially transmissive for EUV radiation but substantially blocking for other wavelengths of radiation such as infrared radiation.

The radiation source SO (or radiation system) can further include a fuel target imaging system to obtain images of fuel targets (e.g., droplets) in the plasma formation region 404 or, more particularly, to obtain images of shadows of the fuel targets. The fuel target imaging system can detect light diffracted from the edges of the fuel targets. References to images of the fuel targets in the following text should be understood also to refer to images of shadows of the fuel targets or diffraction patterns caused by the fuel targets.

The fuel target imaging system can include a photodetector such as a CCD array or a CMOS sensor, but it will be appreciated that any imaging device suitable for obtaining images of the fuel targets can be used. It will be appreciated that the fuel target imaging system can include optical components, such as one or more lenses, in addition to a photodetector. For example, the fuel target imaging system can include a camera 410, e.g., a combination of a photosensor or photodetector and one or more lenses. The optical components can be selected so that the photosensor or camera 410 obtains near-field images and/or far-field images. The camera 410 can be positioned within the radiation source SO at any appropriate location from which the camera has a line of sight to the plasma formation region 404 and one or more markers (not shown in FIG. 4) provided on the radiation collector 405. In some aspects, however, it can be necessary to position the camera 410 away from the propagation path of the one or more laser beams 402 and from the trajectory of the fuel targets emitted from fuel target generator 403 so as to avoid damage to the camera 410. According to some aspects, the camera 410 is configured to provide images of the fuel targets to a controller 411 via a connection 412. The connection 412 is shown as a wired connection, though it will be appreciated that the connection 412 (and other connections referred to herein) can be implemented as either a wired connection or a wireless connection or a combination thereof.

As shown in FIG. 4, the radiation source SO can include a fuel target generator 403 configured to generate and emit fuel targets 403′ (e.g., discrete tin droplets) towards a plasma formation region 404. The radiation source SO can further include a laser system 401 configured to hit one or more of the fuel targets 403′ with one or more laser beams 402 for generating a plasma 407 at the plasma formation region 404. The radiation source SO can further include a radiation collector 405 (e.g., a radiation collector CO) configured to collect radiation emitted by the plasma 407.

### Example Illumination Uniformity Correction System

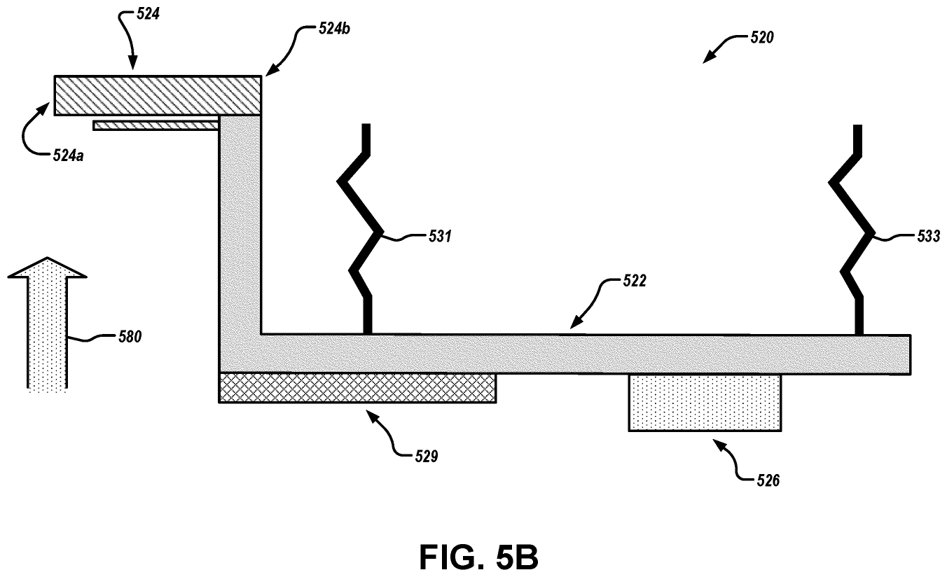

FIGS. 5A and 5B are schematic illustrations of an example illumination uniformity correction system 500 according to some aspects of the present disclosure.

As shown in FIG. 5A, example illumination uniformity correction system 500 can include a set of finger assemblies 502 (e.g., 28 finger assemblies at a pitch of about 4 mm), a set of fingertips 504 (e.g., each finger assembly includes a respective fingertip), a frame 528, a set of flexures 530, and a set of flexures 532. In some aspects, example illumination uniformity correction system 500 can individually control (e.g., using controller 590 and a motion control system that includes, but is not limited to, and one or more magnet assemblies) the position of each finger assembly in the set of finger assemblies 502 to modify the intensity of the illumination slit in order to achieve a target uniformity. In some aspects, the optical edges of one or more fingertips in the set of fingertips 504 can be exposed to radiation 580 (e.g., DUV or EUV radiation) during a wafer exposure operation of a lithographic apparatus, which may cause the one or more fingertips to grow as a result of the exposure (or over the course of multiple exposures).

As shown in FIG. 5B, the set of finger assemblies 502 can include a finger assembly 520. Finger assembly 520 can include a finger body 522, a fingertip 524, an actuator 526 (e.g., to adjust the position of finger assembly 520), a position sensor 529 (e.g., including but not limited to an encoder scale), a flexure 531, and a flexure 533. Fingertip 524 can include an optical edge 524a and a mechanical edge 524b. In some aspects, optical edge 524a of fingertip 524 can be exposed to radiation 580 (e.g., DUV or EUV radiation) during a wafer exposure operation of a lithographic apparatus, which may cause fingertip 524 to grow as a result of the exposure (or over the course of multiple exposures).

Referring now to FIGS. 5A and 5B, in some aspects, example illumination uniformity correction system 500 can include a controller 590 configured to determine a change in a shape of one or more finger assemblies in the set of finger assemblies 502.

In some aspects, the set of finger assemblies 502 can define a maximum exposure field of the uniformity correction system, and a subset of the set of finger assemblies 502 can define an exposure field for a wafer exposure operation. The controller 590 can be configured to determine whether the exposure field is less than the maximum exposure field. In response to a determination that the exposure field is less than the maximum exposure field, the controller 590 can be further configured to modify illumination slit uniformity calibration data associated with the maximum exposure field to generate modified illumination slit uniformity calibration data associated with the exposure field. Subsequently, the controller 590 can be configured to determine an optimal position of a finger assembly 520 in the subset of the set of finger assemblies 502 based on the modified illumination slit uniformity calibration data.

In some aspects, the maximum exposure field can correspond to a maximum illumination slit width of the uniformity correction system, and the exposure field can correspond to an illumination slit width that is less than the maximum illumination slit width. In some aspects, the maximum exposure field can correspond to a full field of the uniformity correction system, and the exposure field can correspond to a partial field (e.g., a shifted or potentially shifted half field) of the uniformity correction system.

In some aspects, the uniformity correction system can further include a motion control system including, but not limited to, actuator 526 coupled to finger body 522. The motion control system can be coupled to the finger assembly 520 and configured to adjust the optimal position of the finger assembly 520. In some aspects, the controller 590 can be further configured to determine a change in a shape of the finger assembly 520.

In one example, the controller 590 can be further configured to determine a change in a position of an optical edge 524a of a fingertip 524 of the finger assembly 520 based on a growth of the fingertip 524 in response to an exposure of the fingertip 524 to DUV or EUV radiation. The controller 590 can be further configured to determine the change in the shape of the finger assembly 520 based on the determined change in the position of the optical edge 524a of the fingertip 524 of the finger assembly 520.

In another example, the controller 590 can be further configured to measure a change in a position of a reference mark disposed on the finger assembly 520. The controller 590 can be further configured to determine the change in the shape of the finger assembly 520 based on the measured change in the position of the reference mark.

In some aspects, the controller 590 can be further configured to generate a control signal configured instruct the motion control system to adjust the optimal position of the finger assembly 520 based on the modified illumination slit uniformity calibration data and the determined change in the shape of the finger assembly 520. The controller 590 can be further configured to transmit the control signal to the motion control system.

In one illustrative and non-limiting example, controller 590 can be configured to determine a change in a position of optical edge 524a of fingertip 524 of finger assembly 520 based on a growth of fingertip 524 in response to an exposure of fingertip 524 to radiation 580. Controller 590 can be configured to generate a control signal configured to modify a position of finger assembly 520 based on the determined change in the shape of finger assembly 520. Controller 590 can be further configured to transmit the control signal to a motion control system coupled to the finger assembly 520, such as actuator 526 coupled to finger body 522.

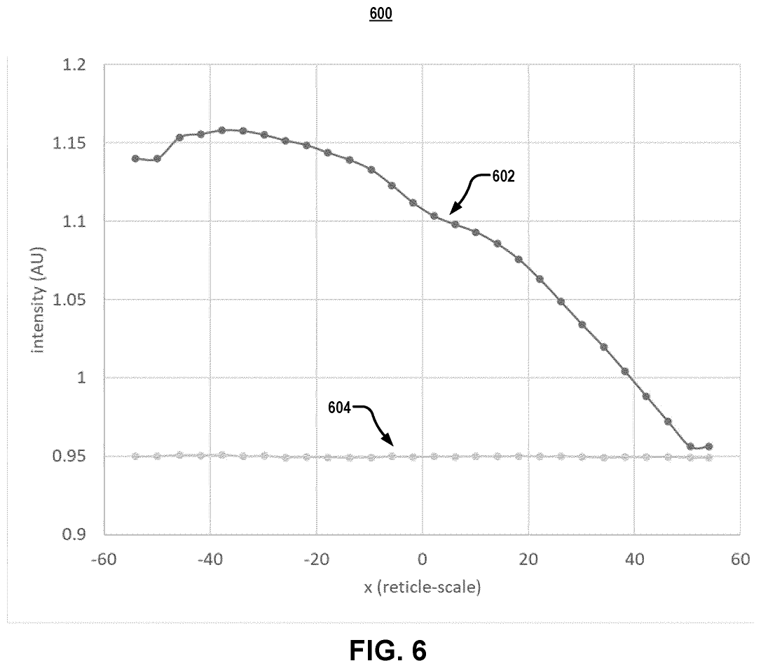

FIG. 6 shows an example graph 600 showing example illumination slit uniformity calibration data for a maximum exposure field (e.g., “open slit” or “full field”) according to some aspects of the present disclosure. As shown in FIG. 6, example graph 600 includes a measured intensity curve 602 for the maximum exposure field and illumination slit uniformity calibration data 604 associated with the maximum exposure field. Illumination slit uniformity calibration data 604 can be used, for example, to provide Unicom correction for the maximum exposure field. However, if only the left side of the reticle (a shifted over half field or quarter field) is used for exposure, then the outcome of UR is still at a low level that accompanies the full calibration data (e.g., 0.95 arbitrary units (AU) may be copied as the intensity for the small field UR).

FIG. 7 shows an example graph 700 showing example modified illumination slit uniformity calibration data for a partial exposure field (e.g., a left half field) according to some aspects of the present disclosure. As shown in FIG. 7, example graph 700 includes a measured intensity curve 702 for the partial exposure field, illumination slit uniformity calibration data 704 associated with the maximum exposure field, and modified illumination slit uniformity calibration data 706 associated with the partial exposure field. Modified illumination slit uniformity calibration data 706 can be used, for example, to provide Unicom correction for the partial exposure field. In some aspects, illumination slit uniformity calibration data 704 may set all image-widths at a 0.95 level, and modified illumination slit uniformity calibration data 706 may depend on data within each field image-width and thus can set the image-width at an over 1.10 level. As a result, illuminator transmission can be optimized for substantially all cases (e.g., about a 17% benefit for this example).

### Example Processes for Adjusting Illumination Slit Uniformity

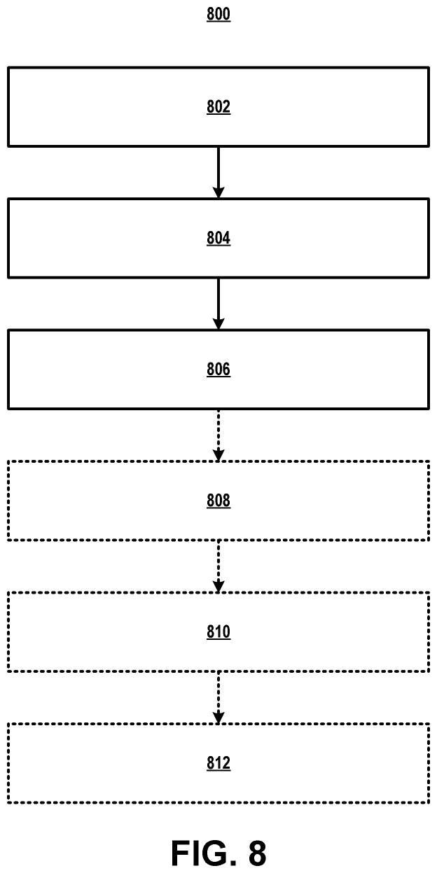

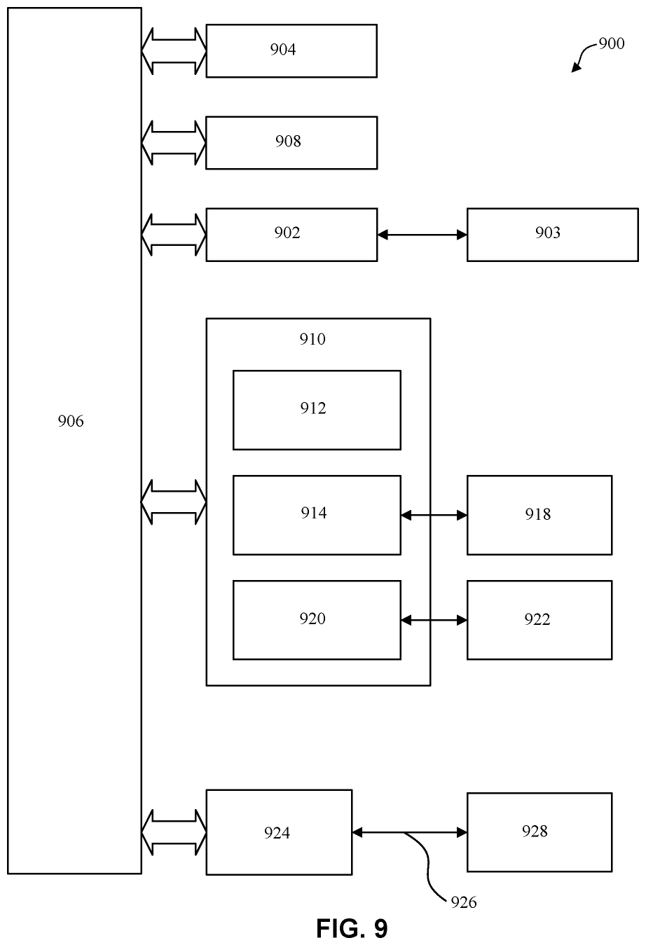

FIG. 8 is an example method 800 for adjusting illumination slit uniformity in a lithographic apparatus according to some aspects of the present disclosure or portion(s) thereof. The operations described with reference to example method 800 can be performed by, or according to, any of the systems, apparatuses, components, techniques, or combinations thereof described herein, such as those described with reference to FIGS. 1-7 above and FIG. 9 below.

At operation 802, the method can include determining, by a controller (e.g., controller 590), whether an exposure field for a wafer exposure operation is less than a maximum exposure field of a uniformity correction system (e.g., the example illumination uniformity correction system 500). In some aspects, the uniformity correction system can include a plurality of finger assemblies (e.g., the set of finger assemblies 502), where the maximum exposure field is defined by the plurality of finger assemblies, and the exposure field is defined by a subset of the plurality of finger assemblies (e.g., a subset of the set of finger assemblies 502). In some aspects, the maximum exposure field can correspond to a maximum illumination slit width of the uniformity correction system, and the exposure field can correspond to an illumination slit width that is less than the maximum illumination slit width. In some aspects, the maximum exposure field can correspond to a full field of the uniformity correction system, and the exposure field can correspond to a partial field (e.g., a shifted or potentially shifted half field) of the uniformity correction system. In some aspects, the determination of whether the exposure field is less than the maximum exposure field can be accomplished using suitable mechanical or other methods and include determining whether the exposure field is less than the maximum exposure field in accordance with any aspect or combination of aspects described with reference to FIGS. 1-7 above and FIG. 9 below.

At operation 804, the method can include modifying, by the controller and in response to determining that the exposure field is less than the maximum exposure field, illumination slit uniformity calibration data associated with the maximum exposure field to generate modified illumination slit uniformity calibration data associated with the exposure field. In some aspects, the modification of the illumination slit uniformity calibration data can be accomplished using suitable mechanical or other methods and include modifying the illumination slit uniformity calibration data in accordance with any aspect or combination of aspects described with reference to FIGS. 1-7 above and FIG. 9 below.

At operation 806, the method can include determining, by the controller, an optimal position of a finger assembly (e.g., a finger assembly in the set of finger assemblies 502) of the uniformity correction system based on the modified illumination slit uniformity calibration data. In some aspects, the determination of the optimal position of the finger assembly can be accomplished using suitable mechanical or other methods and include determining the optimal position of the finger assembly in accordance with any aspect or combination of aspects described with reference to FIGS. 1-7 above and FIG. 9 below.

Optionally, at optional operation 808, the method can include determining, by the controller, a change in a shape of the finger assembly.

In some aspects, the determining the change in the shape of the finger assembly can include determining, by the controller, a change in a position of an optical edge of a fingertip of the finger assembly based on a growth of the fingertip in response to an exposure of the fingertip to DUV radiation or EUV radiation and determining, by the controller, the change in the shape of the finger assembly based on the determined change in the position of the optical edge of the fingertip of the finger assembly.

In some aspects, the determining the change in the shape of the finger assembly can include measuring, by the controller, a change in a position of a reference mark disposed on the finger assembly and determining, by the controller, the change in the shape of the finger assembly based on the measured change in the position of the reference mark. In some aspects, the determination of the change in the shape of the finger assembly can be accomplished using suitable mechanical or other methods and include determining the change in the shape of the finger assembly in accordance with any aspect or combination of aspects described with reference to FIGS. 1-7 above and FIG. 9 below.

Optionally, at optional operation 810, the method can include generating, by the controller, a control signal configured to instruct a motion control system coupled to the finger assembly to adjust the optimal position of the finger assembly based on the modified illumination slit uniformity calibration data and the determined change in the shape of the finger assembly. In some aspects, the generation of the control signal can be accomplished using suitable mechanical or other methods and include generating the control signal in accordance with any aspect or combination of aspects described with reference to FIGS. 1-7 above and FIG. 9 below.

Optionally, at optional operation 812, the method can include transmitting, by the controller, the control signal to the motion control system. In some aspects, the transmission of the control signal can be accomplished using suitable mechanical or other methods and include transmitting the control signal in accordance with any aspect or combination of aspects described with reference to FIGS. 1-7 above and FIG. 9 below.

### Example Computing System

Aspects of the disclosure can be implemented in hardware, firmware, software, or any combination thereof. Aspects of the disclosure can also be implemented as instructions stored on a machine-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical, or other forms of propagated signals (e.g., carrier waves, infrared signals, digital signals, etc.), and others. Further, firmware, software, routines, instructions, and combinations thereof can be described herein as performing certain actions. However, it should be appreciated that such descriptions are merely for convenience and that such actions in fact result from computing devices, processors, controllers, or other devices executing the firmware, software, routines, instructions, or combinations thereof and, in doing so, causing actuators or other devices (e.g., servo motors, robotic devices) to interact with the physical world.

Various aspects can be implemented, for example, using one or more computing systems, such as example computing system 900 shown in FIG. 9. Example computing system 900 can be a specialized computer capable of performing the functions described herein such as: the example illumination uniformity correction system 500 shown in FIGS. 5A and 5B; any other suitable system, sub-system, or component; or any combination thereof. Example computing system 900 can include one or more processors (also called central processing units, or CPUs), such as a processor 904. Processor 904 is connected to a communication infrastructure 906 (e.g., a bus). Example computing system 900 can also include user input/output device(s) 903, such as monitors, keyboards, pointing devices, etc., that communicate with communication infrastructure 906 through user input/output interface(s) 902. Example computing system 900 can also include a main memory 908 (e.g., one or more primary storage devices), such as random access memory (RAM). Main memory 908 can include one or more levels of cache. Main memory 908 has stored therein control logic (e.g., computer software) and/or data.

Example computing system 900 can also include a secondary memory 910 (e.g., one or more secondary storage devices). Secondary memory 910 can include, for example, a hard disk drive 912 and/or a removable storage drive 914. Removable storage drive 914 can be a floppy disk drive, a magnetic tape drive, a compact disk drive, an optical storage device, tape backup device, and/or any other storage device/drive.

Removable storage drive 914 can interact with a removable storage unit 918. Removable storage unit 918 includes a computer usable or readable storage device having stored thereon computer software (control logic) and/or data. Removable storage unit 918 can be a floppy disk, magnetic tape, compact disk, DVD, optical storage disk, and/or any other computer data storage device. Removable storage drive 914 reads from and/or writes to removable storage unit 918.

According to some aspects, secondary memory 910 can include other means, instrumentalities or other approaches for allowing computer programs and/or other instructions and/or data to be accessed by example computing system 900. Such means, instrumentalities or other approaches can include, for example, a removable storage unit 922 and an interface 920. Examples of the removable storage unit 922 and the interface 920 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

Example computing system 900 can further include a communications interface 924 (e.g., one or more network interfaces). Communications interface 924 enables example computing system 900 to communicate and interact with any combination of remote devices, remote networks, remote entities, etc. (individually and collectively referred to as remote devices 928). For example, communications interface 924 can allow example computing system 900 to communicate with remote devices 928 over communications path 926, which can be wired and/or wireless, and which can include any combination of LANs, WANs, the Internet, etc. Control logic, data, or both can be transmitted to and from example computing system 900 via communications path 926.

The operations in the preceding aspects of the present disclosure can be implemented in a wide variety of configurations and architectures. Therefore, some or all of the operations in the preceding aspects can be performed in hardware, in software or both. In some aspects, a tangible, non-transitory apparatus or article of manufacture includes a tangible, non-transitory computer useable or readable medium having control logic (software) stored thereon is also referred to herein as a computer program product or program storage device. This includes, but is not limited to, example computing system 900, main memory 908, secondary memory 910 and removable storage units 918 and 922, as well as tangible articles of manufacture embodying any combination of the foregoing. Such control logic, when executed by one or more data processing devices (such as example computing system 900), causes such data processing devices to operate as described herein.

Based on the teachings contained in this disclosure, it will be apparent to persons skilled in the relevant art(s) how to make and use aspects of the disclosure using data processing devices, computer systems and/or computer architectures other than that shown in FIG. 9. In particular, aspects of the disclosure can operate with software, hardware, and/or operating system implementations other than those described herein.

The embodiments may further be described using the following clauses:

1. A system, comprising:
a uniformity correction system comprising:
   a plurality of finger assemblies,
   wherein the plurality of finger assemblies defines a maximum exposure field of the uniformity correction system, and
   wherein a subset of the plurality of finger assemblies defines an exposure field for a wafer exposure operation; and
a controller configured to:
   determine whether the exposure field is less than the maximum exposure field;
   in response to a determination that the exposure field is less than the maximum exposure field, modify illumination slit uniformity calibration data associated with the maximum exposure field to generate modified illumination slit uniformity calibration data associated with the exposure field; and
   determine an optimal position of a finger assembly in the subset of the plurality of finger assemblies based on the modified illumination slit uniformity calibration data.
      2. The system of clause 1, wherein:
the maximum exposure field corresponds to a maximum illumination slit width of the uniformity correction system; and
the exposure field corresponds to an illumination slit width that is less than the maximum illumination slit width.
   3. The system of clause 1, wherein:
the maximum exposure field corresponds to a full field of the uniformity correction system; and
the exposure field corresponds to a partial field of the uniformity correction system.
   4. The system of clause 1, wherein:
the uniformity correction system further comprises a motion control system coupled to the finger assembly and configured to adjust the optimal position of the finger assembly; and
the controller is further configured to:
   determine a first change in a shape of the finger assembly;
   generate a control signal configured instruct the motion control system to adjust the optimal position of the finger assembly based on the modified illumination slit uniformity calibration data and the determined first change in the shape of the finger assembly; and
   transmit the control signal to the motion control system.
      5. The system of clause 4, wherein the controller is further configured to:
determine a second change in a position of an optical edge of a fingertip of the finger assembly based on a growth of the fingertip in response to an exposure of the fingertip to deep ultraviolet (DUV) radiation or extreme ultraviolet (EUV) radiation; and
determine the first change in the shape of the finger assembly based on the determined second change in the position of the optical edge of the fingertip of the finger assembly.
   6. The system of clause 4, wherein the controller is further configured to:
measure a second change in a position of a reference mark disposed on the finger assembly; and
determine the first change in the shape of the finger assembly based on the measured second change in the position of the reference mark.
   7. An apparatus, comprising:
a controller configured to:
   determine whether an exposure field for a wafer exposure operation is less than a maximum exposure field of a uniformity correction system;
   in response to a determination that the exposure field is less than the maximum exposure field, modify illumination slit uniformity calibration data associated with the maximum exposure field to generate modified illumination slit uniformity calibration data associated with the exposure field; and
   determine an optimal position of a finger assembly of the uniformity correction system based on the modified illumination slit uniformity calibration data.
      8. The apparatus of clause 7, wherein:
the uniformity correction system comprises a plurality of finger assemblies;
the maximum exposure field is defined by the plurality of finger assemblies;
the exposure field is defined by a subset of the plurality of finger assemblies; and
the subset of the plurality of finger assemblies comprises the finger assembly.
   9. The apparatus of clause 7, wherein:
the maximum exposure field corresponds to a maximum illumination slit width of the uniformity correction system; and
the exposure field corresponds to an illumination slit width that is less than the maximum illumination slit width.
   10. The apparatus of clause 7, wherein:
the maximum exposure field corresponds to a full field of the uniformity correction system; and
the exposure field corresponds to a partial field of the uniformity correction system.
   11. The apparatus of clause 7, wherein the controller is further configured to:
determine a first change in a shape of the finger assembly;
generate a control signal configured instruct a motion control system coupled to the finger assembly to adjust the optimal position of the finger assembly based on the modified illumination slit uniformity calibration data and the determined first change in the shape of the finger assembly; and
transmit the control signal to the motion control system.
   12. The apparatus of clause 11, wherein the controller is further configured to:
determine a second change in a position of an optical edge of a fingertip of the finger assembly based on a growth of the fingertip in response to an exposure of the fingertip to deep ultraviolet (DUV) radiation or extreme ultraviolet (EUV) radiation; and
determine the first change in the shape of the finger assembly based on the determined second change in the position of the optical edge of the fingertip of the finger assembly.
   13. The apparatus of clause 11, wherein the controller is further configured to:
measure a second change in a position of a reference mark disposed on the finger assembly; and
determine the first change in the shape of the finger assembly based on the measured second change in the position of the reference mark.
   14. A method for adjusting illumination slit uniformity in a lithographic apparatus, comprising:
determining, by a controller, whether an exposure field for a wafer exposure operation is less than a maximum exposure field of a uniformity correction system;
in response to determining that the exposure field is less than the maximum exposure field, modifying, by the controller, illumination slit uniformity calibration data associated with the maximum exposure field to generate modified illumination slit uniformity calibration data associated with the exposure field; and
determining, by the controller, an optimal position of a finger assembly of the uniformity correction system based on the modified illumination slit uniformity calibration data.
   15. The method of clause 14, wherein:
the uniformity correction system comprises a plurality of finger assemblies;
the maximum exposure field is defined by the plurality of finger assemblies;
the exposure field is defined by a subset of the plurality of finger assemblies; and
the subset of the plurality of finger assemblies comprises the finger assembly.
   16. The method of clause 14, wherein:
the maximum exposure field corresponds to a maximum illumination slit width of the uniformity correction system; and
the exposure field corresponds to an illumination slit width that is less than the maximum illumination slit width.
   17. The method of clause 14, wherein:
the maximum exposure field corresponds to a full field of the uniformity correction system; and
the exposure field corresponds to a partial field of the uniformity correction system.
   18. The method of clause 14, further comprising:
determining, by the controller, a first change in a shape of the finger assembly;
generating, by the controller, a control signal configured to instruct a motion control system coupled to the finger assembly to adjust the optimal position of the finger assembly based on the modified illumination slit uniformity calibration data and the determined first change in the shape of the finger assembly; and
transmitting, by the controller, the control signal to the motion control system.
   19. The method of clause 18, wherein the determining the first change in the shape of the finger assembly comprises:
determining, by the controller, a second change in a position of an optical edge of a fingertip of the finger assembly based on a growth of the fingertip in response to an exposure of the fingertip to deep ultraviolet (DUV) radiation or extreme ultraviolet (EUV) radiation; and
determining, by the controller, the first change in the shape of the finger assembly based on the determined second change in the position of the optical edge of the fingertip of the finger assembly.
   20. The method of clause 18, wherein the determining the first change in the shape of the finger assembly comprises:
measuring, by the controller, a second change in a position of a reference mark disposed on the finger assembly; and
determining, by the controller, the first change in the shape of the finger assembly based on the measured second change in the position of the reference mark.

Although specific reference may be made in this text to the use of lithographic apparatus in the manufacture of ICs, it should be understood that the lithographic apparatuses described herein can have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein can be processed, before or after exposure, in for example a track unit (a tool that typically applies a layer of resist to a substrate and develops the exposed resist), a metrology unit and/or an inspection unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some aspects, the substrate itself can be patterned and materials added on top of it can also be patterned, or can remain without patterning.

The examples disclosed herein are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

While specific aspects of the disclosure have been described above, it will be appreciated that the aspects can be practiced otherwise than as described. The description is not intended to limit the embodiments of the disclosure.

It is to be appreciated that the Detailed Description section, and not the Background, Summary, and Abstract sections, is intended to be used to interpret the claims. The Summary and Abstract sections may set forth one or more but not all example embodiments as contemplated by the inventor(s), and thus, are not intended to limit the present embodiments and the appended claims in any way.

Some aspects of the disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects of the disclosure will so fully reveal the general nature of the aspects that others can, by applying knowledge within the skill of the art, readily modify and/or adapt for various applications such specific aspects, without undue experimentation, without departing from the general concept of the present disclosure. Therefore, such adaptations and modifications are intended to be within the meaning and range of equivalents of the disclosed aspects, based on the teaching and guidance presented herein.

The breadth and scope of the present disclosure should not be limited by any of the above-described example aspects or embodiments, but should be defined only in accordance with the following claims and their equivalents.

1. A system, comprising:
a uniformity correction system comprising:
a plurality of finger assemblies,
wherein the plurality of finger assemblies defines a maximum exposure field of the uniformity correction system, and
wherein a subset of the plurality of finger assemblies defines an exposure field for a wafer exposure operation; and
a controller configured to:
determine whether the exposure field is less than the maximum exposure field;
in response to a determination that the exposure field is less than the maximum exposure field, modify illumination slit uniformity calibration data associated with the maximum exposure field to generate modified illumination slit uniformity calibration data associated with the exposure field; and
determine an optimal position of a finger assembly in the subset of the plurality of finger assemblies based on the modified illumination slit uniformity calibration data.

2. The system of claim 1, wherein:
the maximum exposure field corresponds to a maximum illumination slit width of the uniformity correction system; and
the exposure field corresponds to an illumination slit width that is less than the maximum illumination slit width.

3. The system of claim 1, wherein:
the maximum exposure field corresponds to a full field of the uniformity correction system; and
the exposure field corresponds to a partial field of the uniformity correction system.

4. The system of claim 1, wherein:
the uniformity correction system further comprises a motion control system coupled to the finger assembly and configured to adjust the optimal position of the finger assembly; and
the controller is further configured to:
determine a first change in a shape of the finger assembly;
generate a control signal configured instruct the motion control system to adjust the optimal position of the finger assembly based on the modified illumination slit uniformity calibration data and the determined first change in the shape of the finger assembly; and
transmit the control signal to the motion control system.

5. The system of claim 4, wherein the controller is further configured to:
determine a second change in a position of an optical edge of a fingertip of the finger assembly based on a growth of the fingertip in response to an exposure of the fingertip to deep ultraviolet (DUV) radiation or extreme ultraviolet (EUV) radiation; and
determine the first change in the shape of the finger assembly based on the determined second change in the position of the optical edge of the fingertip of the finger assembly.

6. The system of claim 4, wherein the controller is further configured to:
measure a second change in a position of a reference mark disposed on the finger assembly; and
determine the first change in the shape of the finger assembly based on the measured second change in the position of the reference mark.

7. An apparatus, comprising:
a controller configured to:
determine whether an exposure field for a wafer exposure operation is less than a maximum exposure field of a uniformity correction system;
in response to a determination that the exposure field is less than the maximum exposure field, modify illumination slit uniformity calibration data associated with the maximum exposure field to generate modified illumination slit uniformity calibration data associated with the exposure field; and
determine an optimal position of a finger assembly of the uniformity correction system based on the modified illumination slit uniformity calibration data.

8. The apparatus of claim 7, wherein:
the uniformity correction system comprises a plurality of finger assemblies;
the maximum exposure field is defined by the plurality of finger assemblies;
the exposure field is defined by a subset of the plurality of finger assemblies;
the subset of the plurality of finger assemblies comprises the finger assembly;
the maximum exposure field corresponds to a maximum illumination slit width of the uniformity correction system; and
the exposure field corresponds to an illumination slit width that is less than the maximum illumination slit width.

9. The apparatus of claim 7, wherein:
the maximum exposure field corresponds to a full field of the uniformity correction system;
the exposure field corresponds to a partial field of the uniformity correction system; and
the controller is further configured to:
determine a first change in a shape of the finger assembly;
generate a control signal configured instruct a motion control system coupled to the finger assembly to adjust the optimal position of the finger assembly based on the modified illumination slit uniformity calibration data and the determined first change in the shape of the finger assembly; and
transmit the control signal to the motion control system.

10. The apparatus of claim 9, wherein the controller is further configured to:
determine a second change in a position of an optical edge of a fingertip of the finger assembly based on a growth of the fingertip in response to an exposure of the fingertip to deep ultraviolet (DUV) radiation or extreme ultraviolet (EUV) radiation; and
determine the first change in the shape of the finger assembly based on the determined second change in the position of the optical edge of the fingertip of the finger assembly.

11. The apparatus of claim 9, wherein the controller is further configured to:
measure a second change in a position of a reference mark disposed on the finger assembly; and
determine the first change in the shape of the finger assembly based on the measured second change in the position of the reference mark.

12. A method for adjusting illumination slit uniformity in a lithographic apparatus, comprising:
determining, by a controller, whether an exposure field for a wafer exposure operation is less than a maximum exposure field of a uniformity correction system;
in response to determining that the exposure field is less than the maximum exposure field, modifying, by the controller, illumination slit uniformity calibration data associated with the maximum exposure field to generate modified illumination slit uniformity calibration data associated with the exposure field; and
determining, by the controller, an optimal position of a finger assembly of the uniformity correction system based on the modified illumination slit uniformity calibration data.

13. The method of claim 12, wherein:
the uniformity correction system comprises a plurality of finger assemblies;
the maximum exposure field is defined by the plurality of finger assemblies;
the exposure field is defined by a subset of the plurality of finger assemblies;
the subset of the plurality of finger assemblies comprises the finger assembly;
the maximum exposure field corresponds to a maximum illumination slit width of the uniformity correction system; and
the exposure field corresponds to an illumination slit width that is less than the maximum illumination slit width.

14. The method of claim 12, further comprising:
determining, by the controller, a first change in a shape of the finger assembly;
generating, by the controller, a control signal configured to instruct a motion control system coupled to the finger assembly to adjust the optimal position of the finger assembly based on the modified illumination slit uniformity calibration data and the determined first change in the shape of the finger assembly; and
transmitting, by the controller, the control signal to the motion control system, wherein:
the maximum exposure field corresponds to a full field of the uniformity correction system; and
the exposure field corresponds to a partial field of the uniformity correction system.

15. The method of claim 14, wherein the determining the first change in the shape of the finger assembly comprises:
determining, by the controller, a second change in a position of an optical edge of a fingertip of the finger assembly based on a growth of the fingertip in response to an exposure of the fingertip to deep ultraviolet (DUV) radiation or extreme ultraviolet (EUV) radiation; and
determining, by the controller, the first change in the shape of the finger assembly based on the determined second change in the position of the optical edge of the fingertip of the finger assembly.
